(19) United States
(12) Patent Application Publication
(10) Pub. No.: US 2022/0030668 A1
(43) Pub. Date: Jan. 27, 2022

(54) CERAMIC HEATER WITH SHAFT

(71) Applicant: NGK INSULATORS, LTD., Nagoya-City (JP)

(72) Inventors: Tatsuya KUNO, Nagoya-City (JP); Hiroshi TAKEBAYASHI, Handa-City (JP); Kenichiro AIKAWA, Handa-City (JP)

(73) Assignee: NGK INSULATORS, LTD., Nagoya-City (JP)

(21) Appl. No.: 17/450,704

(22) Filed: Oct. 13, 2021

Related U.S. Application Data
(63) Continuation of application No. PCT/JP2020/022835, filed on Jun. 10, 2020.

(30) Foreign Application Priority Data
Jul. 16, 2019 (JP) 2019-130906

(51) Int. Cl. H05B 3/14; H01L 21/687; H05B 3/28

(52) U.S. Cl. CPC H05B 3/143; H05B 3/283; H01L 21/68792

(57) ABSTRACT

A ceramic heater with a shaft includes: a ceramic plate in which resistance heating elements are embedded; a hollow ceramic shaft bonded to a surface on an opposite side of a wafer placement surface of the ceramic plate; multiple vertical grooves provided in an internal circumferential surface of the ceramic shaft in an axial direction; conductive films provided in the multiple vertical grooves, respectively; and connection members that each electrically connect a terminal of the resistance heating elements to a corresponding one of the conductive films.

### BACKGROUND OF THE INVENTION

### 1. Field of the Invention

The present invention relates to a ceramic heater with a shaft.

### 2. Description of the Related Art

A ceramic heater with a shaft, which holds a wafer, has been conventionally used in transfer, exposure, a film formation process such as CVD, cleaning, etching, and microfabrication such as dicing, for a semiconductor wafer. As shown in PTL 1, such a ceramic heater with a shaft is disclosed, which includes: a ceramic plate in which resistance heating elements are embedded; a hollow ceramic shaft bonded to the surface on the opposite side of a wafer placement surface of the ceramic plate; conductive films formed to extend along the internal circumferential wall surface of the ceramic shaft in a vertical direction; and wires that electrically connect the resistance heating elements and the conductive films (see FIG. 5).

### CITATION LIST

### Patent Literature

PTL 1: JP 2017-162878 A

### SUMMARY OF THE INVENTION

However, when the conductive films are formed on the internal circumferential wall surface of the ceramic shaft, there is a possibility that adjacent conductive films may come into contact with each other.

The present invention has been devised to solve such a problem, and it is a main object to avoid contact between adjacent conductive films.

The ceramic heater with a shaft of the present invention includes: a ceramic plate in which resistance heating elements are embedded; a hollow ceramic shaft bonded to a surface on an opposite side of a wafer placement surface of the ceramic plate; multiple vertical grooves provided in an internal circumferential surface of the ceramic shaft in an axial direction; conductive films provided in the multiple vertical grooves, respectively; and connection members that each electrically connect a terminal of the resistance heating elements to a corresponding one of the conductive films.

In the ceramic heater with a shaft, the conductive films are formed in the vertical grooves provided in the internal circumferential surface of the ceramic shaft in the axial direction. Thus, adjacent conductive films are separated by a boundary portion between a vertical groove and a vertical groove of the ceramic shaft. Therefore, adjacent conductive films are unlikely to come into contact with each other due to the existence of such a boundary portion.

In the ceramic heater with a shaft of the present invention, multiple zones of the ceramic plate may be respectively provided with the resistance heating elements, each of which may be provided with two of the terminals independently, and two of the conductive films independently. When rods for supplying power to the resistance heating elements are placed in the inner space of the ceramic shaft, the number of the rods is limited, and accordingly, the number of the resistance heating elements is also limited. However, a conductive film is used instead of a rod herein, thus it is possible to cope with more resistance heating elements.

In the ceramic heater with a shaft of the present invention, the conductive films and the connection members may be covered with an insulating film. In this manner, it is possible to prevent a short-circuit caused by contact between the conductive films or the connection members and another metal member or the like. It is preferable that such an insulating film be an aerosol deposition (AD) film or a thermal spray film.

### BRIEF DESCRIPTION OF THE DRAWINGS

FIG. 1 is a vertical cross-sectional view of a ceramic heater with a shaft of the present embodiment.

FIG. 2 is a partial enlarged view of FIG. 1.

FIG. 3 is a bottom view of the ceramic heater with a shaft.

FIG. 4 is a partial enlarged view of another embodiment.

FIG. 5 is a vertical cross-sectional view of a conventional ceramic heater with a shaft.

### DETAILED DESCRIPTION OF THE INVENTION

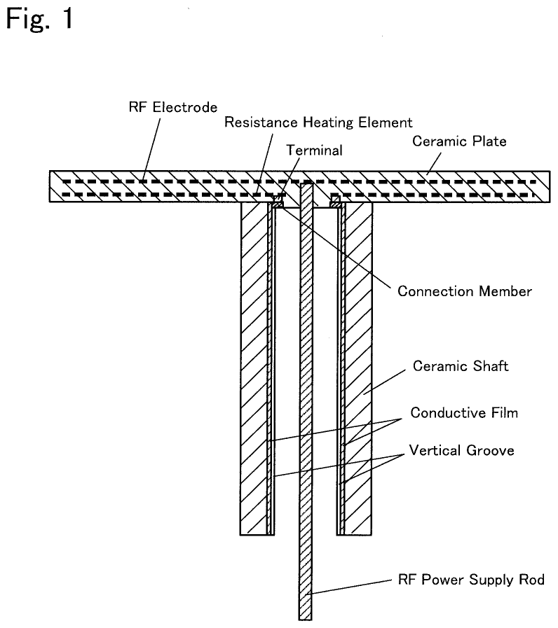

A preferred embodiment of the present invention will be described below with reference to the drawings. FIG. 1 is a vertical cross-sectional view of a ceramic heater with a shaft of the present embodiment.

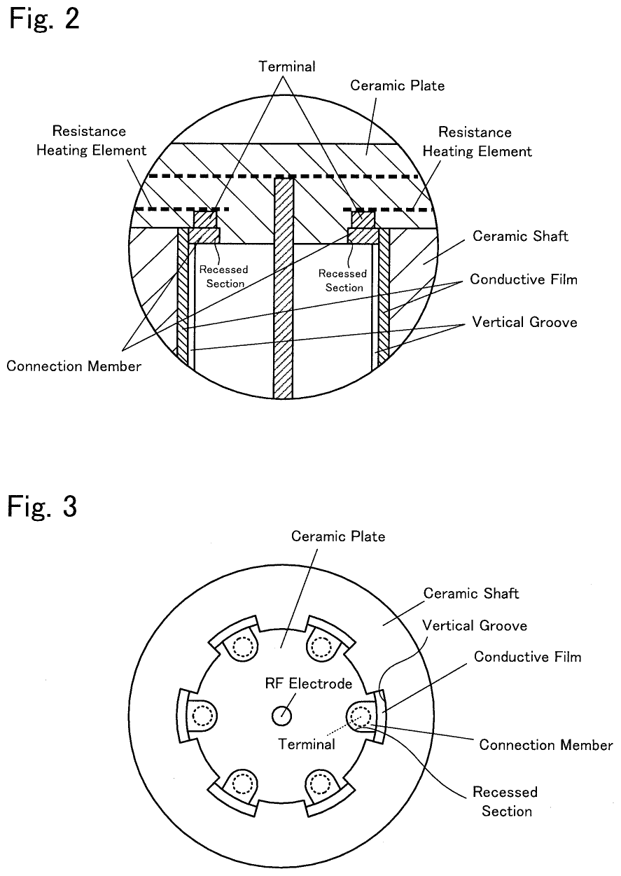

As shown in FIG. 1, the ceramic heater with a shaft includes a ceramic plate, a ceramic shaft, vertical grooves, conductive films, recessed sections (see FIG. 2), and connection members. An RF electrode and resistance heating elements are embedded in the ceramic plate. The RF electrode is an electrode to which a high-frequency voltage is applied when plasma is generated. An RF power supply rod is housed in the inner space of the ceramic shaft, and bonded to the RF electrode from the surface on the opposite side of a wafer placement surface of the ceramic plate. When energized, the resistance heating elements heat the ceramic plate. In the present embodiment, multiple (three) zones of the ceramic plate are provided with the resistance heating elements, respectively. Each of the resistance heating elements is provided with two terminals independently. The ceramic shaft is a hollow shaft which is bonded to the surface on the opposite side of the wafer placement surface of the ceramic plate by direct bonding. The vertical grooves are recessed grooves provided in the internal circumferential surface of the ceramic shaft in an axial direction. In the present embodiment, six vertical grooves are provided at regular intervals (see FIG. 3). The conductive films are provided in the axial direction (vertical direction) so as to respectively extend in the vertical grooves of the ceramic shaft. The conductive films may be formed by printing or plating, or formed by an AD method, a thermal spray method, a CVD method, or a PVD method. Each of the resistance heating elements is provided with two of the conductive films. The recessed sections are U-shaped grooves which are each provided to reach a terminal of a corresponding resistance heating element from the surface on the opposite side of the wafer placement surface of the ceramic plate (see FIG. 2). The lower surface of each terminal is exposed to the bottom surface of a recessed section. The surface of a conductive film is exposed to the side surface of a recessed section. A connection member is filled in a recessed section to electrically connect the lower surface of a terminal of a resistance heating element and the surface of a conductive film. The connection member is obtained by melting wax material placed in a recessed section, then solidifying the wax material.

In the ceramic heater with a shaft of the present embodiment described above, the conductive films are formed in the vertical grooves provided in the internal circumferential surface of the ceramic shaft in the axial direction. Thus, adjacent conductive films are separated by a boundary portion between a vertical groove and a vertical groove of the ceramic shaft. Therefore, adjacent conductive films are unlikely to come into contact with each other due to the existence of such a boundary portion.

When rods for supplying power to the resistance heating elements are placed in the inner space of the ceramic shaft, the number of the rods is limited, and accordingly, the number of the resistance heating elements is also limited. However, a conductive film is used instead of a rod herein, thus it is possible to cope with more resistance heating elements.

Note that the present invention is not particularly limited to the above-described embodiment, and it goes without saying that the present invention can be implemented in various modes as long as it belongs to the technical scope of the invention.

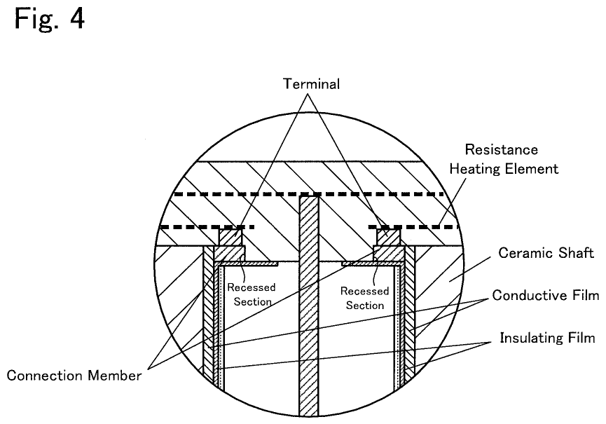

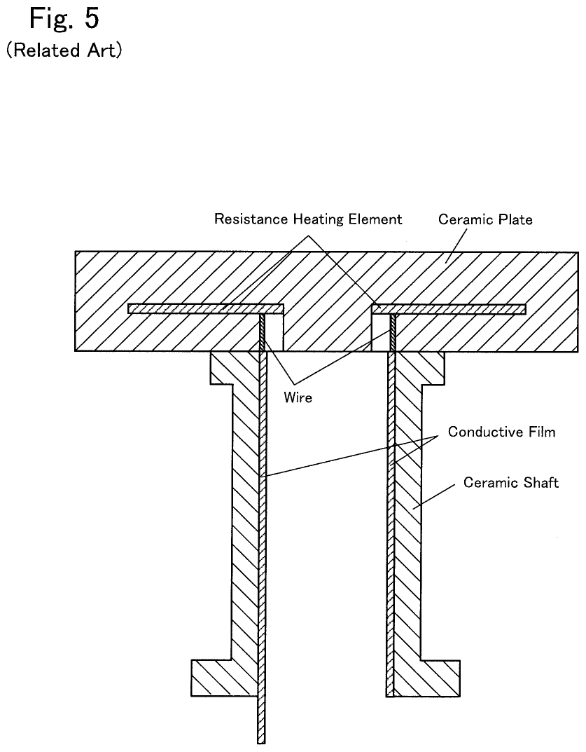

In the embodiment described above, as shown in FIG. 4, the surfaces of the conductive films and the connection members may be covered with an insulating film. In this manner, it is possible to prevent a short-circuit caused by contact of the conductive films or the connection members with another metal member or the like. It is preferable that the insulating film be an aerosol deposition (AD) film or a thermal spray film. Particularly, an AD method (including a plasma AD method) is suitable for forming a thin film of fine ceramic particles with high accuracy. In addition, the AD method allows a film of ceramic particles to be formed by an impact consolidation phenomenon, thus it is not necessary to sinter ceramic particles at a high temperature.

In the above-described embodiment, an electrostatic electrode may be embedded in the ceramic plate.

The present application claims priority from Japanese Patent Application No. 2019-130906, filed on Jul. 16, 2019, the entire contents of which are incorporated herein by reference.

What is claimed is:

1. A ceramic heater with a shaft, comprising:
a ceramic plate in which resistance heating elements are embedded;
a hollow ceramic shaft bonded to a surface on an opposite side of a wafer placement surface of the ceramic plate;
multiple vertical grooves provided in an internal circumferential surface of the ceramic shaft in an axial direction;
conductive films provided in the multiple vertical grooves, respectively; and
connection members that each electrically connect a terminal of the resistance heating elements to a corresponding one of the conductive films.

2. The ceramic heater with a shaft according to claim 1,
wherein multiple zones of the ceramic plate are provided with the resistance heating elements, respectively,
each of the resistance heating elements is independently provided with two of the terminals, and
each of the resistance heating elements is independently provided with two of the conductive films.

3. The ceramic heater with a shaft according to claim 1,
wherein the conductive films and the connection members are covered with an insulating film.

4. The ceramic heater with a shaft according to claim 3,
wherein the insulating film is an aerosol deposition film or a thermal spray film.
